(19) United States
(12) Patent Application Publication
(10) Pub. No.: US 2020/0388699 A1
(43) Pub. Date: Dec. 10, 2020

(54) SEMICONDUCTOR DEVICE AND FABRICATION METHOD THEREOF

(71) Applicants: Semiconductor Manufacturing International (Shanghai) Corporation, Shanghai (CN); Semiconductor Manufacturing International (Beijing) Corporation, Beijing (CN)

(72) Inventor: Nan WANG, Shanghai (CN)

(21) Appl. No.: 16/898,002

(22) Filed: Jun. 10, 2020

(30) Foreign Application Priority Data
Jun. 10, 2019 (CN) 201910497868.X

(51) Int. Cl. H01L 29/66; H01L 29/06; H01L 29/423; H01L 29/786; H01L 21/02; H01L 21/306; H01L 21/3065

(52) U.S. Cl. CPC H01L 29/66742; H01L 29/66545; H01L 29/42392; H01L 29/78681; H01L 29/78684; H01L 29/78696; H01L 21/0214; H01L 21/02164; H01L 21/02167; H01L 21/0217; H01L 21/02603; H01L 21/02532; H01L 21/02546; H01L 21/30621; H01L 21/3065; H01L 29/66522; H01L 29/0673

(57) ABSTRACT

A semiconductor device and a method for forming the semiconductor device are provided. The method includes forming first liner layers and second liner layers alternately disposed over a substrate, where the substrate includes a first region and a second region. The method also includes forming a plurality of fins separately disposed over the substrate by etching the first liner layers, the second liner layers, and a portion of the substrate along a thickness direction. The plurality of fins are disposed over the first region and the second region. In addition, the method includes forming an insulating layer to fully fill a region between adjacent fins disposed over the second region. Further, the method includes forming a dummy gate structure over the substrate, where the dummy gate structure is across the fins.

### CROSS-REFERENCES TO RELATED APPLICATIONS

This application claims the priority of Chinese patent application No. 201910497868.X, filed on Jun. 10, 2019, the entirety of which is incorporated herein by reference.

### FIELD OF THE DISCLOSURE

The present disclosure generally relates to the field of semiconductor manufacturing technology and, more particularly, relates to a semiconductor device and fabrication method thereof.

### BACKGROUND

With the rapid development of semiconductor manufacturing technology, the semiconductor device has been developed toward higher component density and higher integration degree. Transistors, as the most basic semiconductor devices, have been widely used. The control capability of the gate-to-channel current of a conventional planar transistor becomes weak, leading to a short-channel effect and causing a leakage current, thereby affecting the electrical properties of the semiconductor devices.

To overcome the short-channel effect of the transistor and to suppress the leakage current, fin field effect transistors (FinFET) have been developed. A FinFET is one of common multi-gate devices. The FinFET includes a fin disposed on a surface of a semiconductor substrate, an isolation structure covering a portion of a sidewall of the fin, a gate structure disposed over the substrate and across a length portion of the fin, and source and drain regions disposed in the fin on both sides of the gate structure.

To meet the ever-increasing requirements for the performance of the devices, four-sided controlled gate-all-around structures have been developed. A semiconductor device having a gate-all-around structure has a special performance that effectively limits the short-channel effect, and is desirable for the semiconductor industry to continue to reduce the size of the device in accordance with the Moore's Law. The device channel formed by a thin silicon film in the gate-all-around structure is surrounded by the gate of the device, and is only controlled by the gate.

How to form the gate-all-around structure to improve the performance of the semiconductor device is an urgent issue to be solved. The disclosed methods and device structures are directed to solve one or more problems set forth above and other problems.

### BRIEF SUMMARY OF THE DISCLOSURE

One aspect of the present disclosure includes a method for forming a semiconductor device. The method includes forming first liner layers and second liner layers alternately disposed over a substrate, where the substrate includes a first region and a second region. The method also includes forming a plurality of fins separately disposed over the substrate by etching the first liner layers, the second liner layers, and a portion of the substrate along a thickness direction. The plurality of fins are disposed over the first region and the second region. In addition, the method includes forming an insulating layer to fully fill a region between adjacent fins disposed over the second region. Further, the method includes forming a dummy gate structure over the substrate. The dummy gate structure is across the fins.

Another aspect of the present disclosure includes a semiconductor device. The semiconductor device includes a substrate including a first region and a second region, and a plurality of fins separately disposed over the substrate. The plurality of fins are disposed over the first region and the second region, each fin includes a portion of the substrate along a thickness direction, first liner layers and second liner layers. The first liner layers and the second liner layers are alternately disposed over the substrate, and a bottommost layer is a first liner layer. The semiconductor device also includes an insulating layer fully filling a region between adjacent fins disposed over the second region. Further, the semiconductor device includes a dummy gate structure disposed over the substrate, where the dummy gate structure is across the fins.

Another aspect of the present disclosure includes a semiconductor device. The semiconductor device includes a substrate including a first region and a second region, and a plurality of second liner layers separately disposed over the substrate. The plurality of second liner layers are disposed over the first region and the second region. The semiconductor device also includes an insulating layer fully filling a region between adjacent second liner layers disposed over the second region. Further, the semiconductor device includes a gate structure disposed over the substrate, where the gate structure is across the second liner layers.

Other aspects of the present disclosure can be understood by those skilled in the art in light of the description, the claims, and the drawings of the present disclosure.

### BRIEF DESCRIPTION OF THE DRAWINGS

FIGS. 1-6 illustrate semiconductor structures corresponding to certain stages for forming a semiconductor device;

FIGS. 7-10 illustrate semiconductor structures corresponding to certain stages for forming an exemplary semiconductor device consistent with various disclosed embodiments of the present disclosure;

FIGS. 11-17 illustrate semiconductor structures corresponding to certain stages for forming another exemplary semiconductor device consistent with various disclosed embodiments of the present disclosure;

FIG. 18 illustrates an exemplary method for forming a semiconductor device consistent with various disclosed embodiments of the present disclosure; and

FIG. 19 illustrates another exemplary method for forming a semiconductor device consistent with various disclosed embodiments of the present disclosure.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or the alike parts.

In a semiconductor device, a rectangular-shape line end is often obtained using a poly gate cut mask (P2), which can better control the pattern of a gate and increase the density of the semiconductor devices. The method for forming the semiconductor device includes following.

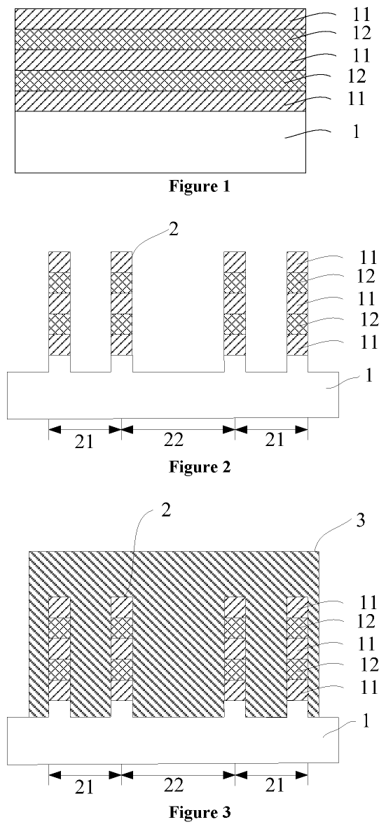

Referring to FIG. 1, a substrate 1 is provided. A first liner layer 11 and a second liner layer 12 are alternately formed on the substrate 1. Referring to FIG. 2, the first liner layer 11, the second liner layer 12, and a portion of the substrate 1 along a thickness direction are etched to form a plurality of fins 2 separately arranged on the substrate 1. The fins 2 are distributed over a first region 21 and a second region 22.

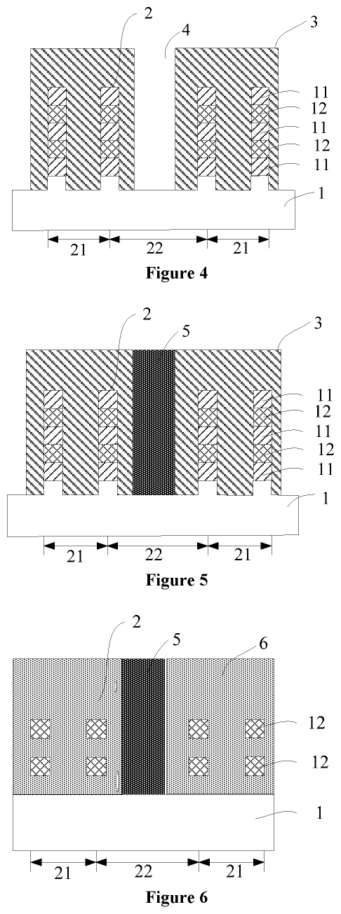

Referring to FIG. 3, a dummy gate structure 3 is formed over the substrate 1, and the dummy gate structure 3 is across a length portion of the fin 2. Referring to FIG. 4, an opening 4 is formed in the dummy gate structure 3, and the opening 4 is located between adjacent fins 2 disposed over the second region 22. Referring to FIG. 5, an insulating layer 5 is formed to fully fill the opening 4. Referring to FIG. 6, the dummy gate structure 3 and the first liner layer 11 are removed, and a gate structure 6 is formed over the substrate 1. The gate structure 6 surrounds the second liner layer 12.

The semiconductor device formed by such method has poor performance stability. At the same time, the formed semiconductor devices have a low integration degree, which limits the application of the semiconductor devices. The reasons for the low integration degree of the formed semiconductor devices include the following. When forming the insulating layer, the insulating layer is formed to fill the opening in the dummy gate structure, and there is the dummy gate structure between the formed insulating layer and the fin. Therefore, there is a certain distance between the insulating layer and the fin, causing a waste of formation space. The reasons for the poor stability of the formed semiconductor device include the following. When removing the dummy gate structure and the first liner layer and forming the gate structure, because the gap between the fin and the insulating layer is substantially small, the air pressure inside the gap has a strong effect on the gate structure, and holes or cracks are easily formed inside the gate structure. The holes or cracks easily cause the failure of the function of the semiconductor device and limit the application of the semiconductor device.

The present disclosure provides a semiconductor device and a method for forming the semiconductor device. After forming fins over the substrate, an insulating layer may be formed to fully fill a region between adjacent fins that desires to cut off a gate structure, and then a dummy gate structure may be formed. The semiconductor devices formed by such method may have a substantially high integration degree, and at the same time, the formed semiconductor devices may have stable performance. Because there is no gap between the insulating layer and the fin, the insulating layer may be in contact with the fin, which may not only improve the spatial integration degree of the semiconductor devices, but also easily obtain a substantially small circuit size due to the elimination of the gap. At the same time, when removing the dummy gate structure and the first liner layer and forming the gate structure, because there is no gap between the fin and the insulating layer, due to absence of resistance, it may be ensured that the formed gate structure may not have defects, e.g., holes or cracks, such that the formed semiconductor device may have stable performance.

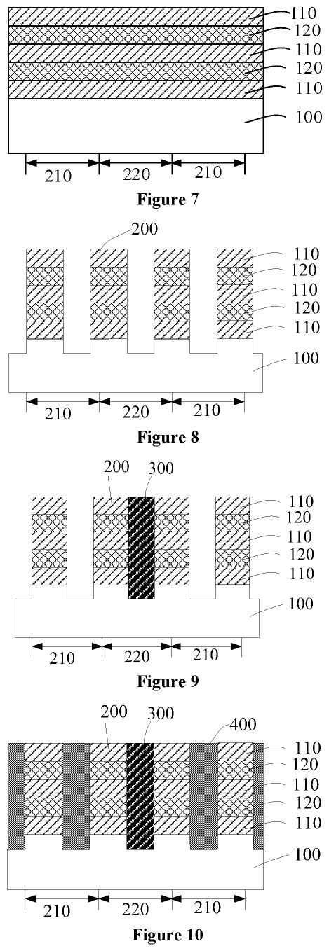

FIG. 18 illustrates a method for forming a semiconductor device consistent with various disclosed embodiments of the present disclosure, and FIGS. 7-10 illustrate semiconductor structures corresponding to certain stages of the fabrication method.

As shown in FIG. 18, at the beginning of the fabrication method, first liner layers and second liner layers may be formed over a substrate (S101). FIG. 7 illustrates a corresponding semiconductor structure.

Referring to FIG. 7, a substrate 100 may be provided, and first liner layers 110 and second liner layers 120 may be alternately formed over the substrate 100. The substrate may include one or more first regions 210 and a second region 220, and the one or more first regions 210 may be disposed on both sides of the second region 220. In one embodiment, the substrate 100 may be made of monocrystalline silicon. In another embodiment, the substrate 100 may be made of polysilicon, amorphous silicon, germanium, silicon germanium, gallium arsenide, or any other semiconductor material.

In one embodiment, the first liner layer 110 may be made of a material different from the second liner layer 120. The first liner layer 110 may be made of silicon germanium (SiGe). In another embodiment, the first liner layer 110 may be made of one or more of silicon, germanium, and gallium arsenide.

In one embodiment, the second liner layer 120 may be made of silicon (Si). In another embodiment, the second liner layer 120 may be made of one or more of silicon germanium, germanium, and gallium arsenide.

In one embodiment, the first liner layer 110 and the second liner layer 120 may be formed over the substrate 100 by an epitaxial growth method. In another embodiment, the first liner layer 110 and the second liner layer 120 may be formed over the substrate 100 by an ion-doped method or a chemical vapor deposition method.

In one embodiment, process parameters for forming the first liner layer 110 may include silane (SiH₄) and germane (GeH₄) as the ambient atmosphere, where the gas percentage ratio of silane (SiH₄) and germane (GeH₄) may be controlled in a range of approximately 20%-50%, a pressure range in a range of approximately 1 Torr-100 Torr, a temperature in a range of approximately 400° C.-600° C., and a reaction time controlled in a range of approximately 10 min-1 h.

In one embodiment, process parameters for forming the second liner layer 120 may include silane (SiH₄) as the ambient atmosphere, where a gas flow rate of the SiH₄ gas may be in a range of approximately 10 sccm-700 sccm, a pressure range in a range of approximately 1 Torr-100 Torr, a temperature in a range of approximately 400° C.-600° C., and a reaction time controlled in a range of approximately 10 min-1 h.

Returning to FIG. 18, after forming the first liner layers and the second liner layers, a plurality of fins may be formed (S102). FIG. 8 illustrates a corresponding semiconductor structure.

Referring to FIG. 8, the first liner layers 110, the second liner layers 120, and a portion of the substrate 100 along a thickness direction may be etched to form a plurality of fins 200 separately arranged over the substrate 100. The fins 200 may be disposed over the one or more first regions 210 and the second region 220.

In one embodiment, when a gate structure is across the fin disposed over the one or more first regions 210, the gate structure may not be cut off. When a gate structure is across the fins disposed over the second region 220, the gate structure between fins disposed over the second region 220 may be cut apart to obtain a rectangular-shape line end.

In one embodiment, the first liner layers 110, the second liner layers 120, and the portion of the substrate 100 along the thickness direction may be dry-etched to form the fins 200 over the substrate 100. In one embodiment, parameters of the dry etching process may include etching gases including HBr and Ar, where a flow rate of HBr may be in a range of approximately 10 sccm-1000 sccm, and a flow rate of Ar may be in a range of approximately 10 sccm-1000 sccm.

Returning to FIG. 18, after forming the plurality of fins, an insulating layer may be formed (S103). FIG. 9 illustrates a corresponding semiconductor structure.

Referring to FIG. 9, an insulating layer 300 may be formed to fully fill a region between the fins 200 disposed over the second region 220. In one embodiment, the insulation layer 300 may be formed to fully fill the region between the fins 200 disposed over the second region 220. In another embodiment, the insulation layer 300 may also be formed to fully fill a region between the fins 200 disposed over the one or more first regions 210.

In one embodiment, the second region 220 may be a cutting region of the gate structure. The cutting region may refer to a region where the gate structure is cut off by the insulating layer 300.

In one embodiment, the insulating layer 300 may be made of silicon oxide. In another embodiment, the insulating layer 300 may be made of one or more of silicon nitride, silicon oxynitride, and silicon carbonitride.

In one embodiment, because the insulating layer 300 fully fills the region between the fins 200 disposed over the second region 220, the insulating layer 300 may be in close contact with the fin 200. Therefore, the gap between the insulating layer 300 and the fin 200 may be eliminated, which may improve the integration degree of the formed semiconductor device and may save space.

Returning to FIG. 18, after forming the insulating layer, a dummy gate structure may be formed (S104). FIG. 10 illustrates a corresponding semiconductor structure.

Referring to FIG. 10, a dummy gate structure 400 may be formed over the substrate 100. The dummy gate structure 400 may be across the fin 200, and a top of the dummy gate structure 400 may be coplanar with a top of the insulating layer 300. In one embodiment, the dummy gate structure 400 may include a dummy gate dielectric layer (not illustrated) and a dummy gate electrode layer. In one embodiment, the dummy gate electrode layer may be made of polysilicon.

In one embodiment, on the one hand, because there is no gap between the insulating layer 300 and the fin 200, space may be saved. At the same time, when forming the dummy gate structure 400, the dummy gate structure 400 may not be formed between the insulating layer 300 and the fin 200. Therefore, when subsequently removing the dummy gate structure 400 and forming a gate structure, there may be no remaining dummy gate structure 400 between the insulating layer 300 and the fin 200. On the other hand, when removing the dummy gate structure 400 and forming the gate structure, defects, e.g., holes or cracks, may not be formed between the fin 200 and the insulating layer 300, and, thus, the performance of the formed semiconductor device may be improved, and the semiconductor device may be ensured to have stable performance.

The present disclosure further provides a semiconductor device formed by the method in any of disclosed embodiments. The semiconductor device may include a substrate 100, and a plurality of fins 200 separately arranged on the substrate 100. The fins 200 may be disposed over a first region 210 and a second region 220, and each fin may include a portion of the substrate 100 along the thickness direction, first liner layers 110 and second liner layers 120. The first liner layers 110 and the second liner layers 120 may be alternately disposed over the substrate 100. The first liner layers 110 may be disposed on the substrate 100 and the second liner layer 120. The second liner layer 120 may be disposed on the first liner layer 110. The semiconductor device may also include an insulating layer 300 fully filling a region between adjacent fins 200 disposed over the second region 220. Further, the semiconductor device may include a dummy gate structure disposed over the substrate 100 and across the fin 200.

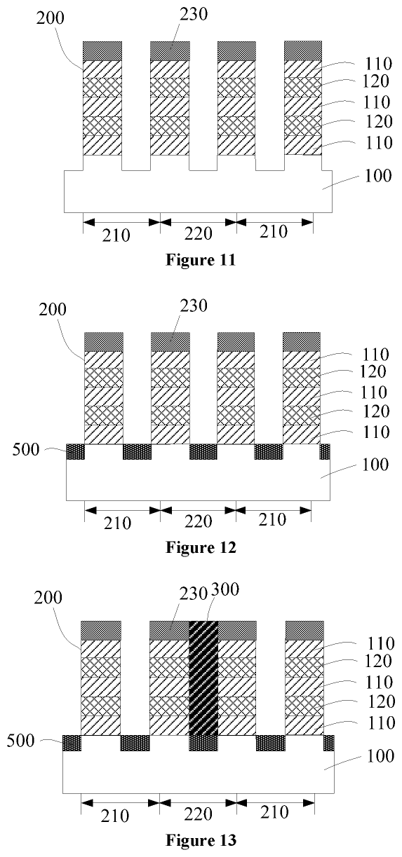

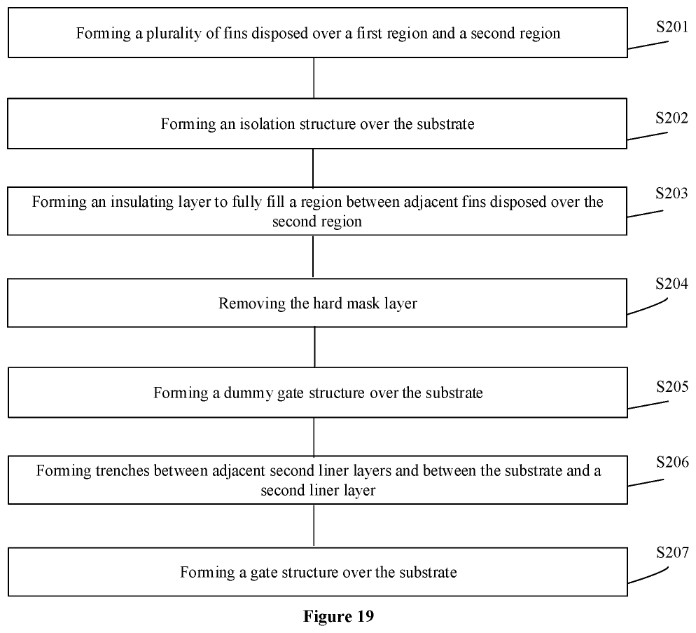

FIG. 19 illustrates a method for forming another semiconductor device consistent with various disclosed embodiments of the present disclosure, and FIGS. 11-17 illustrate semiconductor structures corresponding to certain stages of the fabrication method.

As shown in FIG. 19, at the beginning of the fabrication method, a plurality of fins may be formed (S201). FIG. 11 illustrates a corresponding semiconductor structure.

Referring to FIG. 11, a substrate 100 may be provided, and first liner layers 110 and second liner layers 120 may be alternately formed over the substrate 100. A hard mask layer 230 may be formed on a surface of the first liner layer 110. The hard mask layer 230 may cover locations corresponding to fins. Using the hard mask layer 230 as a mask, the first liner layers 110, the second liner layers 120, and a portion of the substrate along a thickness direction may be etched to form fins 200 over the substrate 100.

In one embodiment, the hard mask layer 230 may be made of silicon nitride. In another embodiment, the hard mask layer 230 may be made of one or more of silicon oxycarbide, silicon carbide, and silicon oxide.

Returning to FIG. 19, after forming the fins, an isolation structure may be formed (S202). FIG. 12 illustrates a corresponding semiconductor structure.

Referring to FIG. 12, an isolation structure 500 may be formed over the substrate 100. The isolation structure 500 may cover a sidewall of the portion of the substrate of the fin 200. In one embodiment, the isolation structure 500 may be formed over the substrate 100.

In one embodiment, the isolation structure 500 may prevent the surface of the substrate 100 from being damaged, thereby facilitating improving the quality of a subsequently formed semiconductor device. In one embodiment, the isolation structure 500 may adopt a shallow trench isolation (STI) structure, and may be formed by a conventional method.

Returning to FIG. 19, after forming the isolation structure, an insulating layer may be formed (S203). FIG. 13 illustrates a corresponding semiconductor structure.

Referring to FIG. 13, an insulating layer 300 may be formed to fully fill a region between the fins 200 disposed over the second region 220. The insulating layer may be formed on the isolation structure. The insulating layer 300 may cover a sidewall of the hard mask layer 230. In one embodiment, a top of the insulating layer 300 may be coplanar with a top of the hard mask layer 230. In one embodiment, the insulating layer 300 may be made of silicon carbide.

In one embodiment, the material of the insulating layer 300 may be formed between adjacent fins 200 by an atomic layer deposition process, and then the material of the insulating layer 300 between adjacent fins 200 disposed over the first region 210 may be back-etched to form the insulating layer 300 fully filling the region between the fins 200 disposed over the second region 220. In certain embodiments, the material of the insulating layer 300 may be formed between the fins 200 by a chemical vapor deposition process or a physical vapor deposition process.

Returning to FIG. 19, after forming the insulating layer, the hard mask layer may be removed (S204). FIG. 14 illustrates a corresponding semiconductor structure.

Referring to FIG. 14, the hard mask layer 230 may be removed. The top of the insulating layer 300 may be above the top of the fin 200. In one embodiment, the hard mask layer 230 may be formed on the top of the fin 200.

In one embodiment, the hard mask layer 230 may be formed to protect the quality of the top surface of the fin 200, such that the top surface of the fin 200 may be prevented from being damaged by subsequent processes. In one embodiment, the hard mask layer 230 may be removed by a dry etching process. In another embodiment, the hard mask layer 230 may be removed by an ashing process.

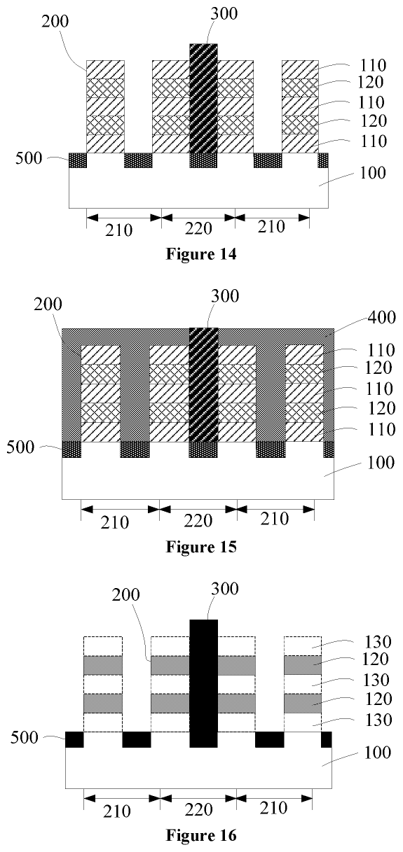

Returning to FIG. 19, after removing the hard mask layer, a dummy gate structure may be formed (S205). FIG. 15 illustrates a corresponding semiconductor structure.

Referring to FIG. 15, a dummy gate structure 400 may be formed over the substrate 100. The dummy gate structure 400 may cover a portion of the sidewall of the insulating layer 300. In one embodiment, a top of the dummy gate structure 400 may be coplanar with the top of the insulating layer 300. The dummy gate structure 400 may be across the fin 200. In one embodiment, the process for forming the dummy gate structure 400 may refer to related descriptions associated with FIG. 10.

The present disclosure further provides a semiconductor device formed by the method in any of disclosed embodiments. The semiconductor device may include a substrate 100, and a plurality of fins 200 separately arranged over the substrate 100. The fins 200 may be disposed over a first region 210 and a second region 220, and each fin may include a portion of the substrate 100 along the thickness direction, first liner layers 110 and second liner layers 120. The first liner layers 110 and the second liner layers 120 may be alternately disposed over the substrate 100. The bottommost layer may be the first liner layer 110, and the topmost layer may also be the first liner layer 110. The semiconductor device may also include an isolation structure 500 disposed over the substrate 100 and covering the sidewall of the portion of the substrate of the fin 200. In addition, the semiconductor device may include an insulating layer 300 fully filling a region between adjacent fins 200 disposed over the second region 220. Further, the semiconductor device may include a dummy gate structure disposed over the substrate 100 and across the fin 200. The dummy gate structure 400 may cover a portion of the sidewall of the insulating layer 300. In one embodiment, a top of the dummy gate structure 400 may be coplanar with the top of the insulating layer 300.

Returning to FIG. 19, after forming the dummy gate structure, trenches may be formed (S206). FIG. 16 illustrates a corresponding semiconductor structure.

Referring to FIG. 16, the dummy gate structure 400 and the first liner layers 110 may be removed to form trenches 130 between adjacent second liner layers 120 and between the substrate 100 and the second liner layer 120.

In one embodiment, the dummy gate structure 400 and the first liner layers 110 may be removed by a wet etching process. The wet etching process may use tetramethylammonium hydroxide (TMAH) as an etching solution, and may use a mixture of tetramethylammonium hydroxide, silicic acid and ammonium persulfate to etch for approximately 2.5 h-3 h to obtain a smooth etched surface.

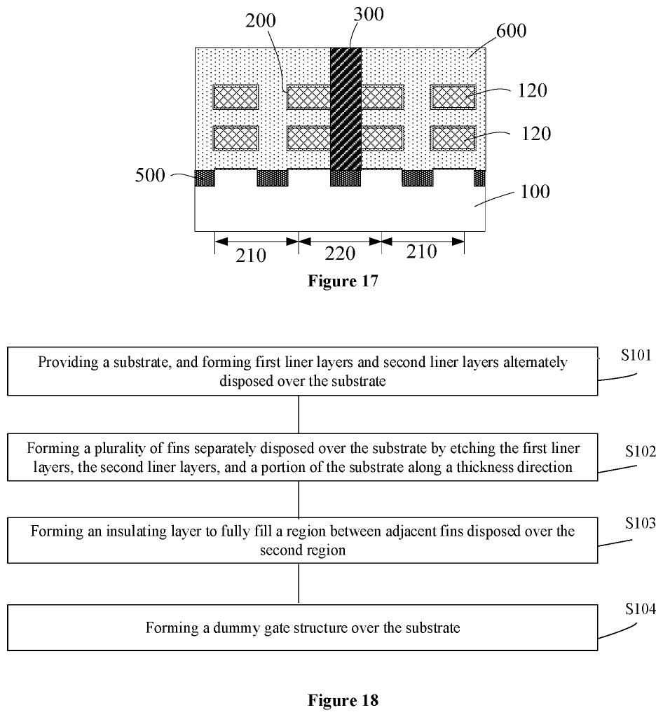

Returning to FIG. 19, after forming the trenches, a gate structure may be formed (S207). FIG. 17 illustrates a corresponding semiconductor structure.

Referring to FIG. 17, a gate structure 600 may be formed over the substrate 100. The gate structure 600 may be across the second liner layers 120 and fully fill the trenches 130. The gate structure 600 may include a gate dielectric layer surrounding the second liner layer 120 and a gate electrode layer covering the gate dielectric layer.

In one embodiment, the formed gate structure 600 surrounding the second liner layer 120 may have a substantially large gate effective width, and the formed semiconductor device may have a capability of effectively limiting the short-channel effect.

In one embodiment, the gate dielectric layer may be made of a high-k dielectric material (e.g., having a dielectric constant greater than 3.9). The high-k dielectric material may include hafnium oxide, zirconium oxide, hafnium oxide silicon, lanthanum oxide, zirconia silicon, titanium oxide, tantalum oxide, barium strontium titanium oxide, barium titanium oxide, titanium strontium oxide, or aluminum oxide.

The gate electrode layer may be made of a metal, and the metal material may include one or more of copper, tungsten, nickel, chromium, titanium, tantalum, and aluminum.

In the disclosed semiconductor device, the fins may be first formed over the substrate. The fin may include the first liner layers, the second liner layers, and the portion of the substrate along the thickness direction. The fins may be disposed over the first region and the second region. The insulating layer for cutting off the gate structure may be formed to fully fill the region between adjacent fins disposed over the second region. After forming the insulating layer, a dummy gate structure may be formed over the substrate.

On the one hand, because the insulating layer is formed to fully fill the region between adjacent fins disposed over the second region, the insulating layer may be in close contact with the fin. Therefore, there may be no gap between the insulating layer and the fin, the integration degree of the formed semiconductor devices may be improved. On the other hand, because the insulating layer is formed before forming the dummy gate structure and fully fills the region between adjacent fins to cut off the formed dummy gate structure, when subsequently removing the dummy gate structure and forming the gate structure, defects, e.g., holes or cracks, may not be formed between the fin and the insulating layer, thereby ensuring the quality of the formed semiconductor device. At the same time, the first liner layers may be removed, and the gate structure may surround the second liner layer. The gate structure surrounding the second liner layer may have a substantially large gate effective width, which may facilitate improving the quality of the formed semiconductor device.

The above detailed descriptions only illustrate certain exemplary embodiments of the present disclosure, and are not intended to limit the scope of the present disclosure. Those skilled in the art can understand the specification as whole and technical features in the various embodiments can be combined into other embodiments understandable to those persons of ordinary skill in the art. Any equivalent or modification thereof, without departing from the spirit and principle of the present disclosure, falls within the true scope of the present disclosure.

What is claimed is:

1. A method for forming a semiconductor device, comprising:
forming first liner layers and second liner layers alternately disposed over a substrate, wherein the substrate includes a first region and a second region;
forming a plurality of fins separately disposed over the substrate by etching the first liner layers, the second liner layers, and a portion of the substrate along a thickness direction, wherein the plurality of fins are disposed over the first region and the second region;
forming an insulating layer to fully fill a region between adjacent fins disposed over the second region; and
forming a dummy gate structure over the substrate, wherein the dummy gate structure is across the fins.

2. The method according to claim 1, wherein:
the insulating layer is made of a material including silicon oxide, silicon nitride, silicon oxynitride, silicon carbonitride, or a combination thereof.

3. The method according to claim 1, after forming the dummy gate structure, further including:
removing the dummy gate structure and the first liner layers, and forming trenches between adjacent second liner layers and between the substrate and a second liner layer; and
forming a gate structure over the substrate, wherein the gate structure is across the second liner layers and fully fills the trenches.

4. The method according to claim 1, wherein:
a first liner layer is made of a material different from a second liner layer.

5. The method according to claim 4, wherein:
the first liner layer is made of a material including silicon, germanium, silicon germanium, gallium arsenide, or a combination thereof; and
the second liner layer is made of a material including silicon, germanium, silicon germanium, gallium arsenide, or a combination thereof.

6. The method according to claim 1, after forming the plurality of fins and before forming the insulating layer, further including:
forming an isolation structure over the substrate, wherein the isolation structure covers a sidewall of the portion of the substrate of the fin, and the insulating layer is formed on the isolation structure.

7. The method according to claim 1, after forming first liner layers and second liner layers and before forming the plurality of fins, further including:
forming a hard mask layer, wherein the hard mask layer is disposed on a top of the fin.

8. The method according to claim 7, after forming the insulating layer and before forming the dummy gate structure, further including:
removing the hard mask layer.

9. The method according to claim 1, wherein:
the first liner layers and the second liner layers are alternately formed over the substrate by an epitaxial growth method.

10. The method according to claim 1, wherein:
a top of the dummy gate structure is coplanar with a top of the insulating layer.

11. A semiconductor device, comprising:
a substrate including a first region and a second region;
a plurality of fins, separately disposed over the substrate, wherein the plurality of fins are disposed over the first region and the second region, each fin includes a portion of the substrate along a thickness direction, first liner layers and second liner layers, wherein the first liner layers and the second liner layers are alternately disposed over the substrate, and a bottommost layer is a first liner layer;
an insulating layer, fully filling a region between adjacent fins disposed over the second region; and
a dummy gate structure, disposed over the substrate, wherein the dummy gate structure is across the fins.

12. The semiconductor device according to claim 11, further including:
an isolation structure disposed over the substrate, wherein the isolation structure covers a sidewall of the portion of the substrate of the fin.

13. The semiconductor device according to claim 11, wherein:
the insulating layer is made of a material including silicon oxide, silicon nitride, silicon oxynitride, silicon carbonitride, or a combination thereof.

14. The semiconductor device according to claim 11, wherein:
a top of the dummy gate structure is coplanar with a top of the insulating layer.

15. The semiconductor device according to claim 11, wherein:
the first liner layer is made of a material different from the second liner layer.

16. The method according to claim 15, wherein:
the first liner layer is made of a material including silicon, germanium, silicon germanium, gallium arsenide, or a combination thereof; and
the second liner layer is made of a material including silicon, germanium, silicon germanium, gallium arsenide, or a combination thereof.

17. A semiconductor device, comprising:
a substrate including a first region and a second region;
a plurality of second liner layers, separately disposed over the substrate, wherein the plurality of second liner layers are disposed over the first region and the second region;
an insulating layer, fully filling a region between adjacent second liner layers disposed over the second region; and
a gate structure, disposed over the substrate, wherein the gate structure is across the second liner layers.

18. The semiconductor device according to claim 17, further including:
an isolation structure disposed over the substrate, wherein the isolation structure covers a sidewall of a portion of the substrate along a thickness direction.

19. The semiconductor device according to claim 17, wherein:
the insulating layer is made of a material including silicon oxide, silicon nitride, silicon oxynitride, silicon carbonitride, or a combination thereof.

20. The semiconductor device according to claim 17, wherein:
a top of the gate structure is coplanar with a top of the insulating layer.
